(19) United States
(12) Patent Application Publication
(10) Pub. No.: US 2026/0344311 A1
(43) Pub. Date: Oct. 29, 2026

(54) METHOD FOR IMPROVING THE CHANNEL MOBILITY IN A SIC MOSFET

(71) Applicant: Hitachi Energy Ltd, Zürich (CH)

(72) Inventors: Yulieth Cristina ARANGO, Zürich (CH); Giovanni ALFIERI, Möriken (CH); Gianpaolo ROMANO, Baden (CH)

(21) Appl. No.: 19/111,464

(22) PCT Filed: Sep. 16, 2022
(86) PCT No.: PCT/EP2022/075822

§ 371 Date: Mar. 13, 2025

(51) Int. Cl. H10P 30/20; H10D 62/832; H10D 62/834; H10P 30/28

(52) U.S. Cl. CPC H10P 30/2042; H10D 62/8325; H10D 62/834; H10P 30/28

(57) ABSTRACT

A method for manufacturing a SiC semiconductor element (10), comprising the steps of providing a SiC substrate (20) with a SiC epitaxial layer (30) on top, treating the SiC epitaxial layer (30) with plasma immersion ion implantation (PIII) using dopants of a first material (35). The method further comprises thermal oxidizing a top surface (31) of the SiC epitaxial layer (30), such that a thermal oxide layer (40) is grown and etching the thermal oxide layer (40). The method further comprises implanting dopants of a second material (36) in the SiC epitaxial layer (30) such that a drain (50) and source (60) are created, activating the dopants with an activation anneal and depositing a metal gate (70).

The present disclosure is related to a method for manufacturing a silicon carbide (SiC) semiconductor element. The present disclosure is further related to a silicon carbide (SiC) semiconductor element for high power switching applications.

Silicon carbide (SiC) is the only compound semiconductor that can be thermally oxidized like silicon. For this reason, thermally grown oxides on SiC can be used as gate dielectric to form metal-oxide-semiconductor (MOS) devices. SiC MOS field effect transistors (MOSFET) are promising candidates for high power switching applications. Low on-resistance and large load currents make it perfect for use as a switching device.

A lateral MOSFET consists of a source and a drain, two highly conducting p-type semiconductor regions which are isolated from the n-type substrate by reversed-biased p-n diodes. A metal gate covers the region between source and drain and is separated from the semiconductor by the gate oxide. The flow of charge carriers from the source to the drain, also known as channel, is controlled by the voltage applied to the gate.

However, with the development of the electronic technology, high temperature, high frequency, etc. enhanced the requirements for semiconductor devices and circuits. Silicon (Si) cannot meet these requirements, in particular for power switches, due to its material properties, and therefore Sic materials have been developed for semiconductor devices operating at high power, high temperature and high frequency. For power switching applications, insulated gate bipolar transistor (IGBTs) and metal oxide semiconductor field effect transistors (MOSFETs) are widely used. These elements have a structure in which the gate electrode portion is electrically insulated from the element body. Since it is only necessary to charge and discharge the capacitor constituted by the gate electrode and the element body, the gate control current is significantly smaller than that of e.g. a gate turn-off transistor.

Despite the high bulk mobility of Sic, low inversion-channel mobilities have been reported in SiC MOSFETs leading to a much higher on-state resistance than what expected from bulk SiC properties. These have been attributed to the large density of interface states Dᵢₜ at the SiO2/SiC interface. Dᵢₜ of SiO2/SiC interface ranges between 10e11 and 10e13 cm-2eV-1 whereas at the SiO2/Si is less than 10e10 cm- 2 eV-1. The nature of Dᵢₜ close to the edge of the conduction band is generally attributed to the presence of C-related defects and intrinsic oxide acceptor defects whereas the nature of Dᵢₜ close to the valence band is mainly attributed to C-related donor defects. The presence of carbon in the SiC epitaxial layer is due to injection during oxidation which gives rise to immobile C-clusters, such as the carbon di-interstitial (Ci)_2.

However, standard ion implantation in SiC gives also rise to electrically active defects that can trap charge carriers. These, in addition to C-related defects formed during oxidation, decrease the charge carrier mobility in the channel.

For n-type channel MOSFET, different ways of reducing Dit have been proposed, such as the post-oxidation annealing (POA) and pre-oxidation implantation (POI). The use of POA, in either N2O or POC13 ambient, or POI, by either N, P or Sb donor impurities, results in a decrease of Dᵢₜ in the upper part of SiC band gap (1e11 cm-2eV-1 for POA, low 1e12 cm-2eV-1 for POI) and increase of the carrier mobility (90 cm2V-1s-1 for POA and 20-100 cm2V-1s-1 for POI). The reason for the reduction of Dᵢₜ, and subsequent carrier mobility increase, has been explained in terms of N (or P) atoms passivating the C-clusters. The increase of the carrier mobility was also explained in terms of counter-doping. By this mechanism, accumulation of N or P or Sb in the channel region, close to the surface, passivates interface defects and increases the electron mobility in the n-channel by converting the epitaxial layer doping from p- to n-type. Nevertheless, both POA and POI have some drawbacks that can affect the reliability of the manufactured devices: The concentration of incorporated N or P is difficult to control by POA and flat-band voltage shift, due to the introduction of N or Por Sb in SiO2, can occur. In addition, since P is more easily incorporated into SiC than N, normally-on devices can be obtained.

It is an object to avoid a large density of interface states at the SiO2/SiC interface.

It is a further object to increase the carrier mobility in the channel of the SiC semiconductor element.

This objects are solved by the features of the independent claims.

Therefore, there is provided a method for manufacturing a SiC semiconductor element, where neither post-oxidation annealing nor pre-oxidation implantation is required. Furthermore, there is provided a corresponding Sic semiconductor element.

Plasma immersion ion implantation (PIII) or pulsed-plasma doping (pulsed PIII) is a surface modification technique of extracting the accelerated ions from a plasma by applying a high voltage pulsed DC or pure DC power supply and targeting them into a suitable substrate or electrode with a semiconductor wafer placed over it, so as to implant it with suitable dopants. The electrode is a cathode for an electropositive plasma, while it is an anode for an electronegative plasma. Plasma can be generated in a suitably designed vacuum chamber with the help of various plasma sources such as electron cyclotron resonance plasma source, which yields plasma with the highest ion density, and lowest contamination level, helicon plasma source, capacitively coupled plasma source, inductively coupled plasma source, DC glow discharge and metal vapor arc. The vacuum chamber can be of two types—diode and triode type depending upon whether the power supply is applied to the substrate as in the former case or to the perforated grid as in the latter.

Accordingly the method for manufacturing a SiC semiconductor element comprises the steps of providing a Sic substrate with a SiC epitaxial layer on top, treating the SiC epitaxial layer with plasma immersion ion implantation (PIII) using dopants of a first material. The method further comprises thermal oxidizing the surface of the SiC epitaxial layer such that a thermal oxide layer (40) is grown and etching the thermal oxide layer (40). The method further comprises implanting dopants of a second material in the SiC epitaxial layer such that a drain and source are created, activating the dopants with an activation anneal and depositing a metal gate.

The method for manufacturing a SiC semiconductor element comprises an optional step of a further plasma immersion ion implantation using Si.

The method for manufacturing a SiC semiconductor element comprises a further optional step of a plasma immersion ion implantation using Ar to preamorphize the SiC epitaxial layer before treating the SiC epitaxial layer with plasma immersion ion implantation (PIII) using dopants of the first material.

By use of the described method for manufacturing a Sic semiconductor element it is possible to counteract the aforementioned adverse effects due to the specifically performed plasma immersion ion implantation.

It is possible to reduce the density of interface states Dit at the SiO2/SiC interface and subsequent increase the carrier mobility.

In addition the optional step of Si PIII further improves the carrier mobility. During oxidation, such Si-rich layer will be oxidized and the formation of C-clusters will be minimized, leading to an increase of the carrier mobility in the channel of the SiC semiconductor element.

The additional step of Ar PIII enables making the channel region deeper.

A silicon carbide (SiC) semiconductor element comprises a SiC semiconductor substrate having a top surface and a bottom surface, a SiC epitaxial layer having a top surface and a bottom surface. The SiC epitaxial layer is formed on the top surface of the SiC semiconductor substrate. The SiC semiconductor element further comprising a source and drain structure formed in the top surface of the SiC epitaxial layer, a thermal oxide and a metal gate, and a first region with dopants of first material, which may be a part of a channel. The thermal oxide covers the first region, at least part of the source structure and at least part of the drain structure. Thus the metal gate is electrically insulated from the first region, the source structure and the drain structure by the thermal oxide and overlaps the first region and at least part of the source and drain structure.

The SiC semiconductor element optionally comprises a second region, which is treated with PIII with Si.

The SiC semiconductor element optionally comprises a with Ar preamorphized SiC epitaxial layer.

The SiC semiconductor substrate is a 3C-SiC substrate, a 4H-SiC substrate or a 6H-SiC substrate.

The SiC substrate is n-doped or p-doped and the SiC epitaxial layer is n-doped or p-doped in the same way as the Sic substrate.

The SiC semiconductor element can be used as a SiC transistor. The SiC transistor may be an Insulated Gate Bipolar Transistor (IGBT) or a Metal-Oxide-Semiconductor Field-Effect Transistor (MOSFET), a SiC junction Field-Effect transistor (SiC-JFET) or a SiC bipolar junction transistors (SiC-BJT), for example.

Finally, it is pointed out that all the proposed features and methods can be used solely, but also a combination of two or more.

The present disclosure is related to implantation of dopants in SiC semiconductor elements XYZXYZ

As a result of that the described SiC semiconductor element can be manufactured by the described embodiments of the method, described features and characteristics of the method are also disclosed with respect to the SiC semiconductor element and vice versa. Thus, the present disclosure comprises several aspects, wherein every feature described with respect to one of the aspects is also disclosed herein with respect to the other aspect, even if the respective feature is not explicitly mentioned in the context of the specific aspect.

Exemplary embodiments are explained in the following with the aid of schematic drawings and reference numbers. The figures show:

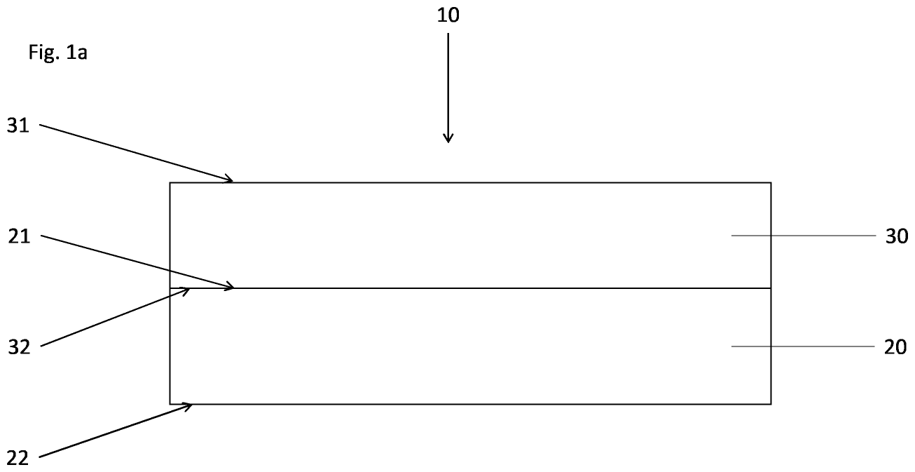

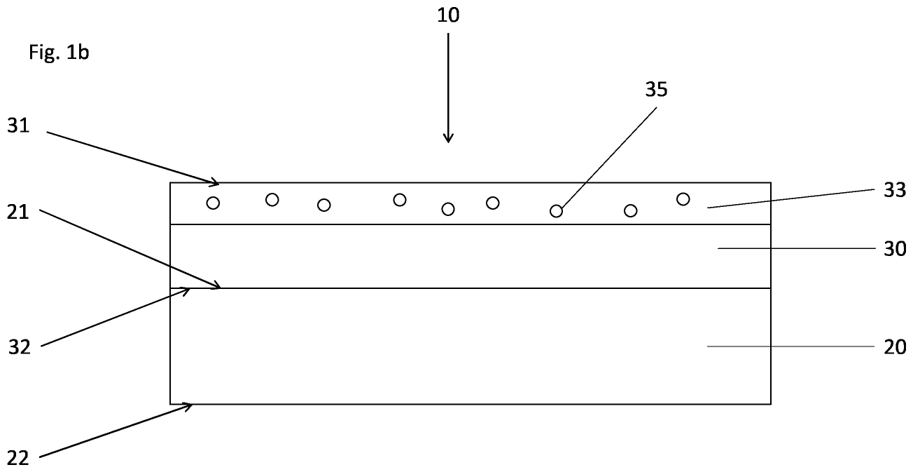

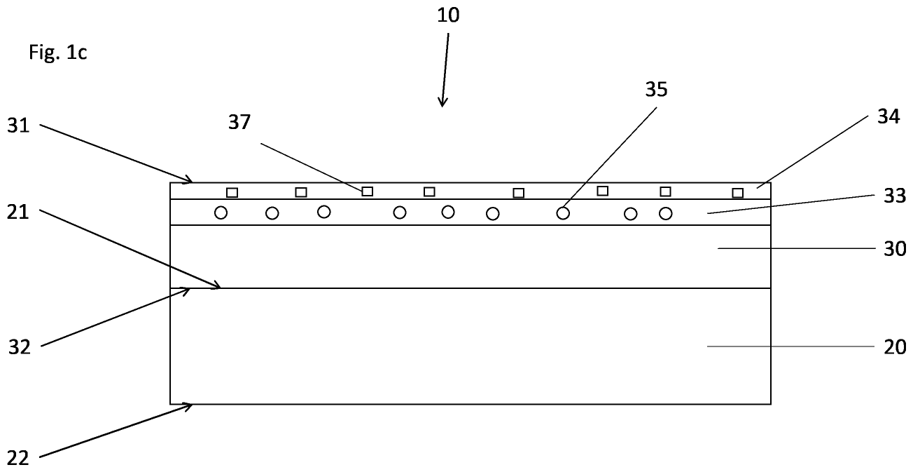

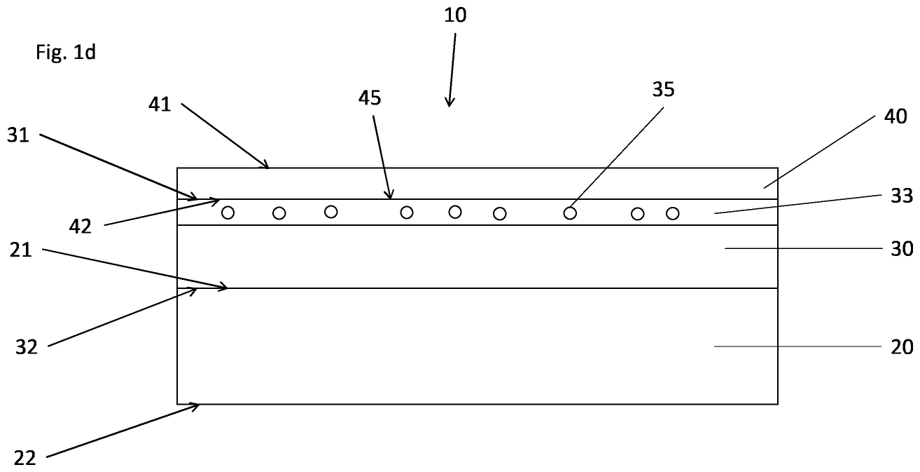

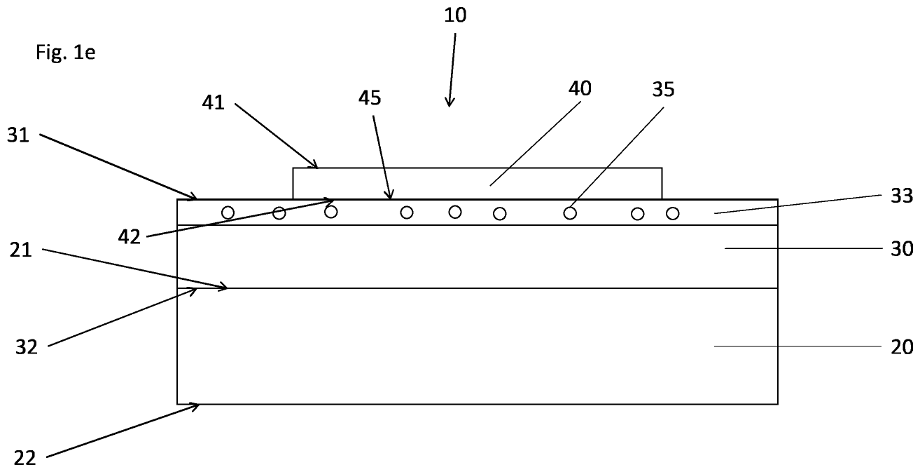

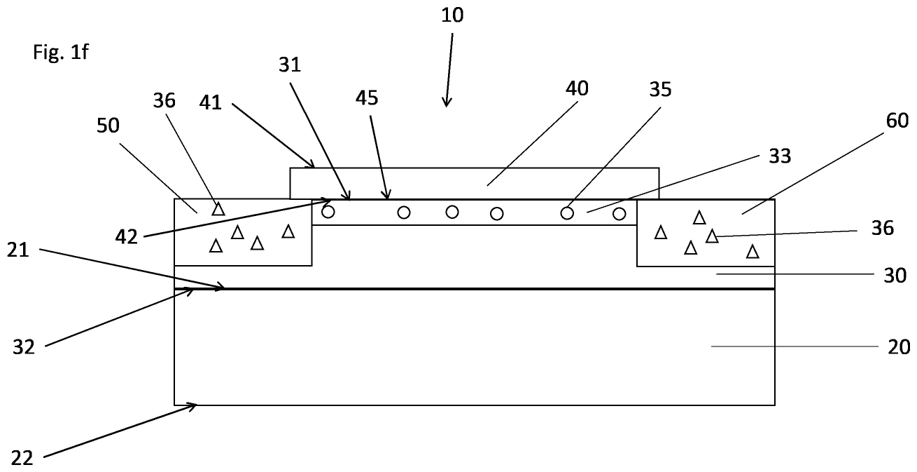

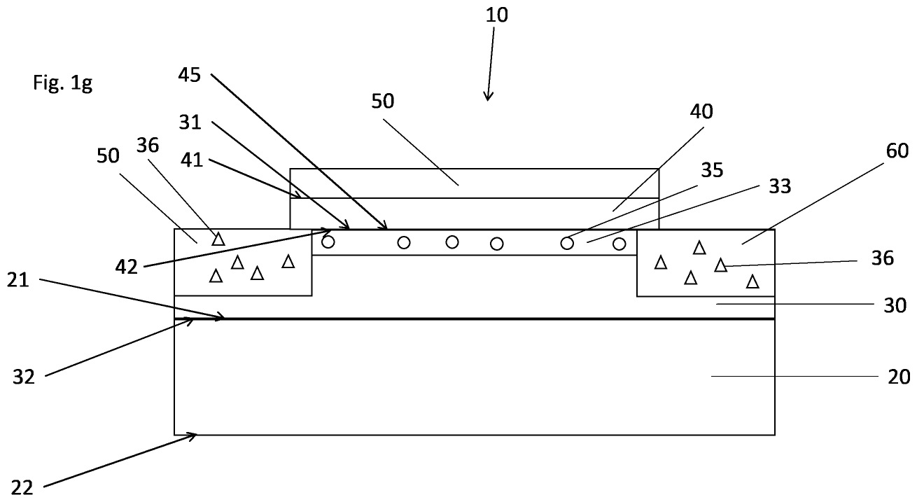

FIGS. 1a-1g Steps of manufacturing a SiC semiconductor element,

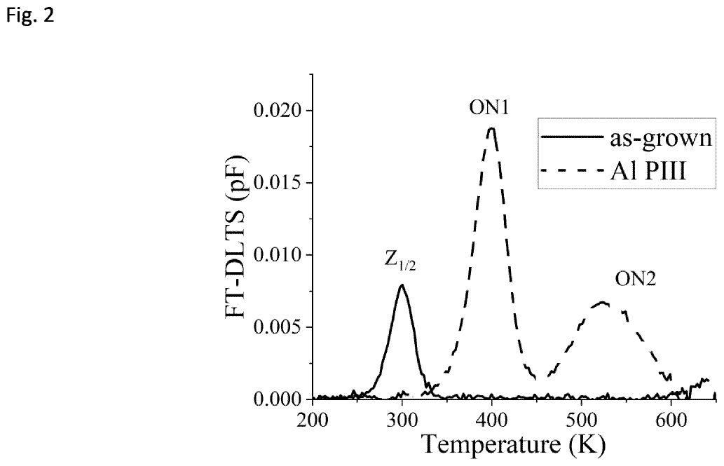

FIG. 2 DLTS spectra of as-grown and PIII treated 4H-SiC.

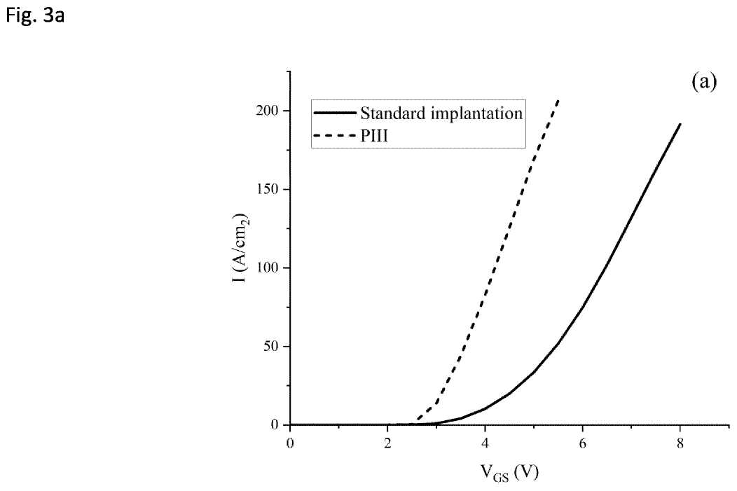

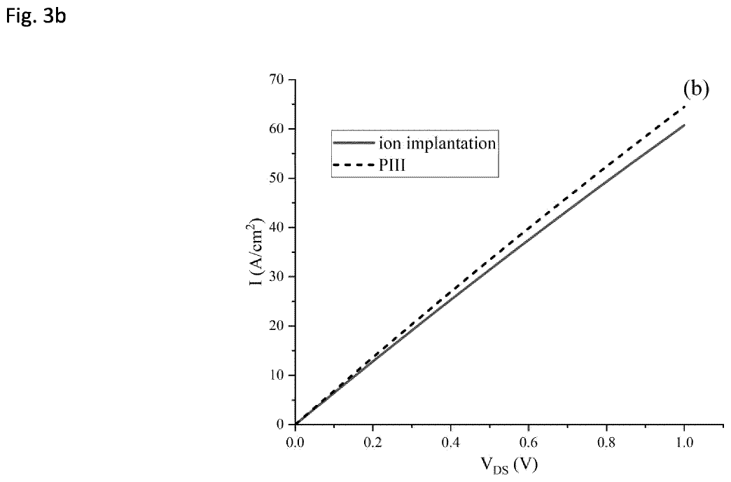

FIGS. 3a, 3b Transfer and output characteristics of a MOSFET.

The accompanying figures are included to provide a further understanding. It is to be understood that the embodiments shown in the figures are illustrative representations and are not necessarily drawn to scale. Identical reference numbers designate elements or components with identical functions. In so far as elements or components correspond to one another in terms of their function in different figures, the description thereof is not repeated for each of the following figures. For the sake of clarity elements might not appear with corresponding reference symbols in all figures possibly.

FIG. 1a to FIG. 1g show the steps of the method for manufacturing a semiconductor element 10.

In this respect terms like “above”, “under”, “top”, “upper” and “bottom” refer to an orientation or direction as illustrated in the figures and with respect to the stacking direction A. Thus, a height or thickness of the described elements is related to the stacking direction A whereas a lateral direction B is orientated perpendicular to the stacking direction A (see FIGS. 1a to 1g).

In FIG. 1a a SiC substrate 20 with a top surface 21 and a bottom surface 22 is provided. On the top surface 21 of the SiC substrate 20 is a SiC epitaxial layer 30 with a bottom surface 31 and a top surface 32. The bottom surface 31 of the SiC epitaxial layer 30 faces the top surface 21 of the Sic substrate 20. The SiC substrate 20 can be n-doped or p-doped with a concentration of at least 1e18 cm-3. The SiC epitaxial layer 30 is doped in the same way as the SiC substrate 20 and can also be n-doped or p-doped with a concentration between 1e14 cm-3 and 1e16 cm-3. The SiC substrate 20 may be a 3C-SiC substrate, a 4H-SiC substrate or a 6H-SiC substrate, for example. In case of a 3C-SiC epitaxial layer, the SiC substrate 20 may be replaced by a Silicon (Si) substrate, for example.

FIG. 1b illustrates treating the SiC epitaxial layer 30 with plasma immersion ion implantation (PIII) creating a first region 33 in the SiC epitaxial layer 30 with dopants of a first material 35. The doping concentration of the dopants of the first material 35 in the SiC epitaxial layer 30 is in the range of 1e16-1e20 cm-3. The dopants of the first material 35 for n-doped semiconductor elements 10 can be, for example, of an element coming from group 2 elements (Be, Mg, Ca, Sr, Ba, Ra) or from group 13 elements (B, Al, Ga, In, Tl, Nh). Alternatively, the dopants of the first material 35 for p-doped semiconductor elements 10 can be, for example, of an element coming from group 15 elements (N, P, As, Sb, Bi, Mc) or from group 16 elements (O, S, Se, Te, Po, Lv). For the PIII an energy in the range of 1-30 keV and Aluminum dopants can be used, for example. The implantation is performed at room temperature RT (approx. 20 °C-22 °C) or at a temperature between 300 °C and 500 °C.

After implantation of dopants of the first material 35, FIG. 1c shows an optional step of a further PIII. For this PIII step an energy in the range of 1-15 keV and Silicon as further dopant 37 is used creating a second region 34 in the SiC epitaxial layer 30. The doping concentration of the dopants in the SiC epitaxial layer 30 is in the range of 1e15-1e18 cm-3. The implantation is performed at room temperature RT or at a temperature between 300 °C and 500 °C. In this way, during oxidation, such Si-rich layer 34 will be oxidized and the formation of C-clusters will be minimized, leading to an increase of the carrier mobility.

FIG. 1d shows the manufacturing step after the implantation step of either a dopant of a first material 35, like Al for example, or of a dopant of a first material 35 and Silicon. This step shows thermal oxidization of the top surface 31 of the SiC epitaxial layer 30 such that a thermal oxide layer 40 of SiO2 is grown on top of the SiC epitaxial layer 30. The oxide layer 40 has a top surface 41 and a bottom surface 42. A SiO2/SiC interface 45 is created between the top surface 31 of the SiC epitaxial layer 30 and the bottom surface 42 of the thermal oxide layer 40. Thermal oxidization is performed at a temperature between 1100 °C and 1400 °C.

The density of interface states Dit at the SiO2/SiC interface 45 is in a typical MOSFET standard implantation in the order of approximately 1e12-1e13 cm-2eV-1. If both, Al and Si PIII are used, the density of interface states Dit is smaller than 1e12 cm-2eV-1 and the ON-resistance R on decreases by 8-10%.

The carrier mobility in the channel in a typical MOSFET standard implantation is approximately 20-50 cm2/Vs. If both, Al and Si PIII are used, the carrier mobility in the channel is higher than 100 cm2 /Vs.

After standard channel implantation, the concentration of carbon vacancies (Vc) in the SiC epitaxial layer is higher than 1e14 cm-3. If Al PIII is used, the concentration of carbon vacancies (Vc) is lower than 1e11 cm-3. If Si PIII is performed on top of the Al PIII the concentration of carbon vacancies (Vc) is even lower.

Additionally the SiC epitaxial layer 30 can be treated with plasma immersion ion implantation (PIII) using Ar with an energy in the range of 5-10 keV to preamorphize the Sic epitaxial layer 30 before treating the SiC epitaxial layer 30 with plasma immersion ion implantation (PIII) using dopants of the first material 35 and/or Si. The Ar PIII contributes to make the channel deeper.

FIG. 1e shows a thermal oxide layer 40, which is etched back at the edges of the thermal oxide layer 40 until the SiC epitaxial layer 30 with the doped first region 33 underneath, is visible.

FIG. 1f shows an implantation of dopants of a second material 36 in the SiC epitaxial layer 30 such that a drain 50 and a source 60 are created. The implantation happens at RT or at a temperature between 300 °C and 500 °C. The concentration of the dopants of the second material 36 is in the range of 1e17-1e21 cm-3, but at least one magnitude higher than the concentration of the dopants of the first material used in the PIII, with Al for example. The implantation can be an n+-implantation with n-dopants, for example. The implantation is followed by an activation annealing for 30 min at a temperature between 1600 °C and 1700 °C. The activation annealing is a heat treatment, which compensates the implantation damage caused by the dopants.

In the step shown in FIG. 1g a metal gate 50 is deposited on top 41 of the etched back thermal oxide layer 40.

This is a basic lateral structure, but the disclosure of the embodiments extends its application to vertical SiC MOSFET devices as well.

The SiC semiconductor element 10 can be used as a Sic transistor. The SiC transistor may be an Insulated Gate Bipolar Transistor (IGBT) or a Metal-Oxide-Semiconductor Field-Effect Transistor (MOSFET), a SiC junction Field-Effect transistor (SiC-JFET) or a SiC bipolar junction transistors (SiC-BJT), for example.

FIG. 2 shows a diagram of Fourier-transformed deep-level transient spectroscopy (FT-DLTS) spectra of as-grown Sic (solid line) and PIII treated SiC (dashed line). The capacitance (pF) is plotted against the temperature (K).

The idea is to employ plasma immersion ion implantation (PIII) for the formation of the channel. By using standard ion implantation on as-grown SiC, several electrically active levels arise, like EH1 (Ec-0.4 eV), Z1/2 (Ec-0.65 eV), EH3 (Ec-0.72 eV), EH4 (Ec-0.8 eV), EH5 (Ec-1.0 eV) and EH6/7 (Ec-1.6 eV). The concentrations of these levels are in the 1e13-1e15 cm-3 range. These electron traps contribute to hinder the carrier mobility in the channel. On the other hand, PIII does not lead to the formation of electrically active levels, except for two levels, labelled ON1 and ON2, which do not have any impact on device functionality. In this way, it is possible to allow the seamless flow of charge carriers in the channel, without any trapping effect from electrical traps.

FIGS. 3a and 3b show simulated output and transfer characteristics for a MOSFET with the channel formed by standard ion implantation (solid line) and PIII (dashed line).

FIG. 3a shows that the simulated devices have the same threshold voltage (V_th). Thus, the gain in the ON-resistance R_on is attributed only to the lower defects density.

FIG. 3b shows the output characteristics when PIII is employed. It can be seen that the curve of the PIII treated MOSFET (dashed line) shows an improvement with respect to standard ion implantation (solid line), meaning that the R_on has decreased.

The embodiments shown in the FIGS. 1 to 3 as stated represent exemplary embodiments of the improved SiC semiconductor element 10 and the manufacturing method for; therefore, they do not constitute a complete list of all embodiments. Actual arrangements and methods may vary from the embodiments shown in terms of SiC semiconductor elements 10, for example.

### REFERENCE SIGNS

10 SiC semiconductor element
20 SiC substrate
21 top surface of the SiC substrate
22 bottom surface of the SiC substrate
30 SiC epitaxial layer
31 top surface of the SiC epitaxial layer
32 bottom surface of the SiC epitaxial layer
33 first region of SiC epitaxial layer
34 second region of SiC epitaxial layer
35 dopants of a first material
36 dopants of a second material
37 further dopant Si
40 thermal oxide layer
41 top surface of thermal oxide layer
42 bottom surface of thermal oxide layer
45 SiO2/SiC interface
50 drain
60 source
70 metal gate

1. A method for manufacturing a SiC semiconductor element, comprising the following steps:
providing a SiC substrate with a SiC epitaxial layer on top,
treating the SiC epitaxial layer with plasma immersion ion implantation using dopants of a first material,
treating the SiC epitaxial layer with a further plasma immersion ion implantation using Si, which is performed with an energy in the range of 1-15 keV with a doping concentration of the Si in the SiC epitaxial layer in the range of 1e15-1e18 cm-3 at room temperature RT or at a temperature between 300 °C and 500 °C,
thermal oxidizing a top surface of the SiC epitaxial layer, which is treated with plasma immersion ion implantation using Si, such that a thermal oxide layer is grown
etching the thermal oxide layer,
implanting dopants of a second material in the SiC epitaxial layer such that a drain and source are created,
activating the dopants with an activation anneal and
depositing a metal gate on the grown thermal oxide layer.

2. A method for manufacturing a SiC semiconductor element according to claim 1, wherein
the PIII is performed with an energy in the range of 1-30 keV using dopants of the first material with a doping concentration in the SiC epitaxial layer in the range of 1e16-1e20 cm-3 at room temperature RT or at a temperature between 300 °C and 500 °C.

3. A method for manufacturing a SiC semiconductor element according to claim 1, wherein
the implantation is performed at room temperature RT or a temperature between 300 °C and 500 °C using dopants of the second material with a doping concentration in the SiC epitaxial layer in the range of 1e17-1e21 cm-3, and wherein the doping concentration of the dopants of the second material in the SiC epitaxial layer is at least one order of magnitude higher than the doping concentration of the dopants of the first material in the SiC epitaxial layer.

4. A method for manufacturing a SiC semiconductor element according to claim 1, wherein
the activation anneal is performed for 30 min at a temperature between 1600 °C and 1700 °C.

5. A method for manufacturing a SiC semiconductor element according to claim 1, comprising:
treating the SiC epitaxial layer with plasma immersion ion implantation with an energy in the range of 5-10 keV using Ar to preamorphize the SiC epitaxial layer before treating the SiC epitaxial layer with plasma immersion ion implantation using dopants of the first material.

6. A SiC semiconductor element comprising:
a SiC substrate,
a SiC epitaxial layer, treated with plasma immersion ion implantation with dopants of a first material, which is performed with an energy in the range of 1-30 keV with a doping concentration of the first material in the SiC epitaxial layer in the range of 1e16-1e20 cm-3 at room temperature RT or at a temperature between 300 °C and 500 °C and
treated with a further plasma immersion ion implantation with Si, which is performed with an energy in the range of 1-15 keV with a doping concentration of the Si in the SiC epitaxial layer in the range of 1e15-1e18 cm-3 at room temperature RT or at a temperature between 300 °C and 500 °C,
a thermal oxide layer grown on the SiC epitaxial layer, which is treated with plasma immersion ion implantation using Si,
a drain,
a source, and
a metal gate on top of the thermal oxide layer.

7. A semiconductor element according to claim 6, wherein
the dopants of the first material used for PIII are coming from group 2 elements (Be, Mg, Ca, Sr, Ba, Ra) or from group 13 elements (B, Al, Ga, In, Tl, Nh).

8. The SiC semiconductor element according to claim 6, wherein
the dopants of the first material used for PIII are Al with an energy in the range of 1-30 keV and with a doping concentration in the SiC epitaxial layer in the range of 1e16-1e20 cm-3.

9. The SiC semiconductor element according to claim 8, wherein the carrier mobility in the channel is higher than 100 cm2 /Vs.

10. The SiC semiconductor element according to claim 8, wherein the density of interface states Dᵢₜ at a SiO2/SiC interface is smaller than 1e12 cm-2eV-1.

11. The SiC semiconductor element according to claim 6, wherein
the dopants of the first material used for PIII are coming from group 15 elements (N, P, As, Sb, Bi, Mc) or from group 16 elements (O, S, Se, Te, Po, Lv).

12. A SiC semiconductor element according to any one of the claim 6, wherein
the SiC substrate is a 3C-SiC substrate, a 4H-SiC substrate or a 6H-SiC substrate.

13. A SiC semiconductor element according to any one of the claim 6, wherein
the SiC substrate is n-doped or p-doped with a doping concentration of at least 1e18 cm-3, and
the SiC epitaxial layer is n-doped or p-doped in the same way as the SiC substrate with a doping concentration in the range of 1e14-1e16 cm-3.

14-15. (canceled)
